(19) United States
(12) Patent Application Publication
(10) Pub. No.: US 2009/0202142 A1
(43) Pub. Date: Aug. 13, 2009

(54) CIRCUIT BOARD, METHOD FOR TESTING CIRCUIT BOARD, AND METHOD FOR MANUFACTURING CIRCUIT BOARD

(76) Inventors: Yukihiro Ishimaru, Osaka (JP); Toshiyuki Kojima, Kyoto (JP); Rikiya Okimoto, Osaka (JP)

Correspondence Address: MCDERMOTT WILL & EMERY LLP, 600 13TH STREET, NW, WASHINGTON, DC, 20005-3096, US

(21) Appl. No.: 12/295,478

(22) PCT Filed: Mar. 30, 2007
(86) PCT No.: PCT/JP2007/057094

§ 371 Date: Nov. 12, 2008

(30) Foreign Application Priority Data
Mar. 31, 2006 (JP) 2006-098810

(51) Int. Cl. G06K 9/00; H05K 1/02; G01R 31/04; H05K 3/34; G01N 21/59; G01N 21/88

(52) U.S. Cl. 382/150; 361/779; 324/537; 29/832; 356/432

(57) ABSTRACT

A circuit board according to the present invention comprises an insulating layer, a first electronic component mounted on the insulating layer, and a solder marker provided on the insulating layer. A first solder having a first melting point constitutes the solder marker. The first electronic component is mounted on the insulating layer via a second solder having a second melting point lower than the first melting point.

### FIELD OF THE INVENTION

The present invention relates to a circuit board provided with an electronic component, more particularly to a technology for checking whether or not any of solder has been re-melted.

### BACKGROUND OF THE INVENTION

As an electronic device is increasingly reduced in size, thinner and more highly-functional in recent years, the demand grows that an electronic component be mounted on a circuit board with a higher density, and the circuit board on which the electronic component is mounted be more highly-functional. Under the circumstances, a board in which electronic components are embedded was developed (refer, for example, to Patent Document 1).

In the board provided with the built-in components, wherein an active component (for example, semiconductor element) and a passive component (for example, capacitor), which are conventionally mounted on a surface of the circuit board, are embedded in the circuit board, an area of the board can be reduced. Further, because a degree of freedom in the allocation of the components can be increased in comparison to the surface mounting, the improvement of high frequency characteristics can be expected because inter-component wiring lines can be optimized.

In the field of ceramic boards, an LTCC (Low Temperature Co-fired Ceramic) board in which the electronic components are embedded was already launched into the market. However, the LTCC board is subject to a number of restrictions in its applications since it is not easily applicable to a large-size board due to its heavy weight and fragility, and it can not have a semiconductor element such as LSI provided therein because it requires a heat process at a high temperature. A circuit board provided with built-in components in which resin is used is recently attracting attention. The board thus constituted is subject to less restrictions relating to the size of the board in comparison to the LTCC board, and also, is advantageous in that the LSI can be embedded therein.

Referring to FIG. 1, the board in which electronic components are incorporated recited in the Patent Document 1 (circuit component-incorporated module) is described. A circuit component-incorporated module 400 illustrated in FIG. 1 comprises a board 401 on which insulating boards 401a, 401b and 401c are multi-layered, wiring patterns 402a, 402b, 402c and 402d formed on a main surface and inside of the board 401, and circuit components 403 connected to the wiring patterns provided inside the board 401. The wiring patterns 402a, 402b, 402c and 402d are electrically connected to one another through inner vias 404, and a blended material including inorganic filler and thermosetting resin constitutes the insulating boards 401a, 401b and 401c.
Patent Document 1: H11-220262 of the Japanese Patent Publication Laid-Open

### DISCLOSURE OF THE INVENTION

### Problems to be Solved by the Invention

In the circuit component-incorporated module 400, wherein the circuit components 403 (403a and 403b) are embedded in the insulating board 401, it cannot be easily checked whether or not soldering which electrically connects the circuit components 403 and the wiring patterns (402a, 402b and 402c) is in a good condition. The condition of the soldering in the circuit component-incorporated module 400 itself may be checked through an electrical test or the like; however, it is particularly difficult to check whether or not the embedded solder is melted again and fails in a reflow process which occurs when the circuit component-incorporated module 400 is secondarily mounted on a wiring board such as a mother board.

In the case where the circuit components are not embedded, as proposed in, for example, No. H08-298360 of the Japanese Patent Publication Laid-Open, pads for evaluating the soldering performance are prepared and solder is melted in the reflow or the like, and then, the size of an area where the melted solder extends is inspected, or an electrical resistance between the pads is measured, so that the soldering performance is evaluated. However, in such aboard structure that the soldered parts illustrated in FIG. 1 are molded with resin, it is not possible to check whether or not the solder is re-melted according to the soldering testing method recited in No. H08-298360. When it is not possible to check whether or not the solder is re-melted, there is a fear that the physical transfer of the re-melted solder may actually deteriorate an insulating property or that the re-melted solder may generate voids in the solder even though the circuit components appear to be electrically connected to one another via the solder. As a result, the reliability may be reduced.

The present invention was made in order to solve the foregoing problems, and a main object thereof is to provide a component-incorporated board or a circuit board provided with a solder marker capable of checking whether or not the solder is re-melted.

### Means for Solving the Problems

A circuit board according to the present invention comprises:
an insulating layer;
an electronic component mounted on the insulating layer; and
a solder marker provided on the insulating layer, wherein
a first solder having a first melting point constitutes the solder maker, and
the electronic component is mounted on the insulating layer via a second solder having a second melting point lower than the first melting point.

A method for testing characteristics of a circuit board according to the present invention is a method for testing characteristics of a circuit board on which an electronic component is mounted via solder when another electronic member is connected thereto, wherein
a solder maker having a first melting point is previously provided in the circuit board, and such another electronic member is connected to the circuit board, and
it is checked whether or not the solder maker is re-melted after such another electronic component is connected so that it is judged whether or not the circuit board is exposed to the first melting point when such another electronic member is connected.

A method for manufacturing a circuit board according to the present invention is a method for manufacturing a circuit board on which an electronic component is mounted, including:
a step of providing a solder marker comprising a first solder having a first melting point in the circuit board and mounting the electronic component on the circuit board via a solder having a melting point equal to the first melting point; and
a step of mounting another electronic component in the circuit board via a second solder having a second melting point lower than the first melting point.

### EFFECT OF THE INVENTION

According to the present invention, when the solder marker provided in a wiring board is checked, it can be checked whether or not the solder having the first melting point is re-melted.

### BRIEF DESCRIPTION OF THE DRAWINGS

FIG. 1 is a perspective view illustrating a constitution of a component-incorporated board including a preferred embodiment of the present invention.

FIG. 2A is a sectional view schematically illustrating a constitution of a circuit board 100 comprising a solder marker 10 according to the preferred embodiment.

FIG. 2B is a sectional view schematically illustrating the constitution of the circuit board 100 comprising the solder marker 10 according to the preferred embodiment.

FIG. 3A is a top view of the solder marker 10 illustrated in FIG. 2A which is X-ray illuminated.

FIG. 3B is a top view of the solder marker 10 illustrated in FIG. 3A which is X-ray illuminated.

FIG. 4A is a sectional view schematically illustrating the constitution of the circuit board 100 comprising the solder marker 10 according to the preferred embodiment.

FIG. 4B is a sectional view schematically illustrating the constitution of the circuit board 100 comprising the solder marker 10 according to the preferred embodiment.

FIG. 5A is a sectional view schematically illustrating the constitution of the circuit board 100 comprising the solder marker 10 according to the preferred embodiment.

FIG. 5B is a sectional view schematically illustrating the constitution of the circuit board 100 comprising the solder marker 10 according to the preferred embodiment.

FIG. 6A is a sectional view of a first process for describing a method for manufacturing the component-incorporated board according to the preferred embodiment.

FIG. 6B is a sectional view of a second process for describing the method for manufacturing the component-incorporated board according to the preferred embodiment.

FIG. 6C is a sectional view of a third process for describing the method for manufacturing the component-incorporated board according to the preferred embodiment.

FIG. 6D is a sectional view of a fourth process for describing the method for manufacturing the component-incorporated board according to the preferred embodiment.

FIG. 7A is a sectional view of a fifth process for describing the method for manufacturing the component-incorporated board according to the preferred embodiment.

FIG. 7B is a sectional view of a sixth process for describing the method for manufacturing the component-incorporated board according to the preferred embodiment.

FIG. 7C is a sectional view of a seventh process for describing the method for manufacturing the component-incorporated board according to the preferred embodiment.

FIG. 8A is a sectional view of a first process for describing a method for testing the component-incorporated board according to the preferred embodiment.

FIG. 8B is a sectional view of a second process for describing the method for testing the component-incorporated board according to the preferred embodiment.

FIG. 9A is a sectional view of a first process for describing a method for testing a component-incorporated module according to the preferred embodiment.

FIG. 9B is a sectional view of a second process for describing the method for testing the component-incorporated module according to the preferred embodiment.

FIG. 10A is a sectional view of a first process for describing a method for testing a mounting body according to the preferred embodiment.

FIG. 10B is a sectional view of a second process for describing a method for testing the mounting body according to the preferred embodiment.

FIG. 11 is a chart illustrating states of an Sn—Sb based material.

FIG. 12A is a table illustrating a relationship between conductive particles and melting points (solid-phase lines).

FIG. 12B is a sectional view illustrating a modified embodiment of the present invention.

FIG. 13A is a top view of the solder marker 10 viewed from above.

FIG. 13B is a top view of the solder marker 10 viewed from above.

FIG. 14A is a top view illustrating a shape of the solder marker.

FIG. 14B is a top view illustrating a shape of the solder marker.

FIG. 14C is a top view illustrating a shape of the solder marker.

FIG. 14D is a top view illustrating a shape of the solder marker.

FIG. 15A is a sectional view schematically illustrating the constitution of the circuit board 100 comprising the solder marker 10 according to the preferred embodiment.

FIG. 15B is a sectional view schematically illustrating the constitution of the circuit board 100 comprising the solder marker 10 according to the preferred embodiment.

FIG. 16A is a sectional view schematically illustrating the constitution of the circuit board 100 comprising the solder marker 10 according to the preferred embodiment.

FIG. 16B is a sectional view schematically illustrating the constitution of the circuit board 100 comprising the solder marker 10 according to the preferred embodiment.

FIG. 17A is a sectional view schematically illustrating the constitution of the circuit board 100 comprising the solder marker 10 according to the preferred embodiment.

FIG. 17B is a sectional view schematically illustrating the constitution of the circuit board 100 comprising the solder marker 10 according to the preferred embodiment.

FIG. 18 is a top view of a constitution wherein the solder marker 10 is provided in an outer frame 150 not included in a region where a component-incorporated board 200 is provided.

### DESCRIPTION OF REFERENCE SYMBOLS

10 solder marker
11 upper-layer board
12 solder
12a melted solder
13 metallic member
14 flux
20 insulating member
20a upper surface
20b lower surface
21 lower-layer board
22 upper-layer board
23 electrode pattern
24 connecting resin layer (composite sheet)
25 housing chamber
26 electrode pattern
27 electrode pattern
28 adhesive
30 electronic component
31 land
32 solder
32a melted solder
40 electronic component
41 land
42 solder
42a melted solder
46 solder ball
51 wiring board (mother board)
100 circuit board
150 outer frame
200 component-incorporated board
300 component-incorporated module
350 mounting body
400 circuit component-incorporated module

### PREFERRED EMBODIMENT OF THE PRESENT INVENTION

Hereinafter, a preferred embodiment of the present invention is described referring to the drawings. In the drawings below, components having substantively the same function are referred to with the same reference symbols in order to simplify the description. The present invention is not limited to the preferred embodiment described below.

### Preferred Embodiment

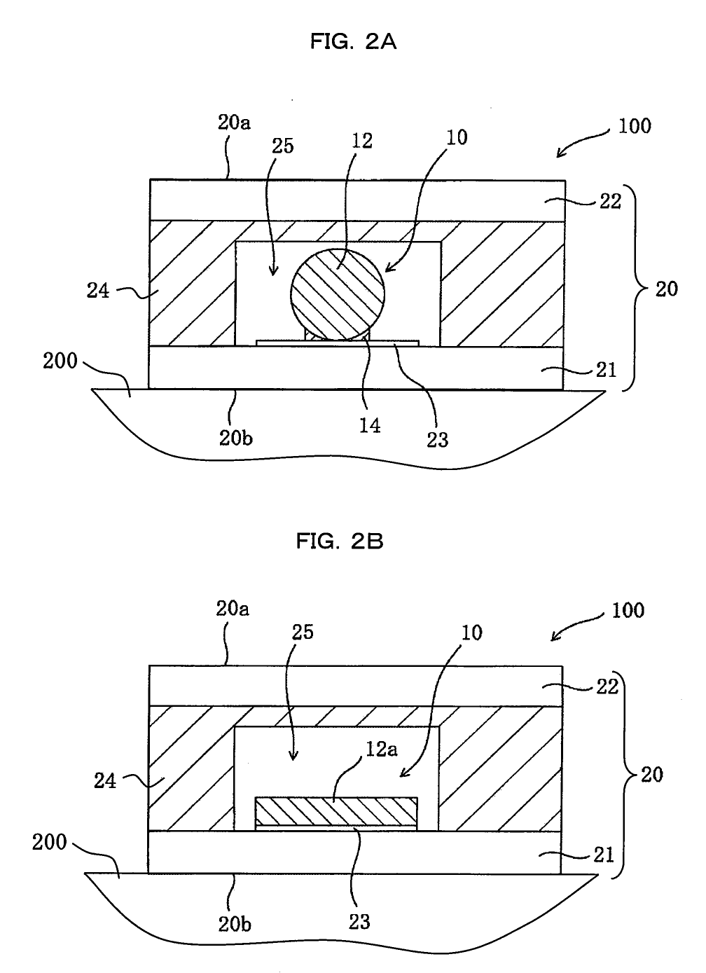

Referring to FIG. 2, a circuit board according to the present preferred embodiment is described.

FIGS. 2A and 2B schematically illustrate a sectional structure of a circuit board 100 comprising a solder marker 10 according to the present preferred embodiment. FIG. 2A illustrates a state of the solder marker 10 indicating that the solder is not re-melted, while FIG. 2B illustrates a state of the solder marker 10 indicating that the solder is re-melted. In terms of a solder reflow process, FIG. 2A illustrates a pre-reflow state, while FIG. 2B illustrates a post-reflow state. The circuit board 100 constitutes, for example, a primary board secondarily mounted on secondary boards (mother boards) 51 and 200 which are an example of another electric member.

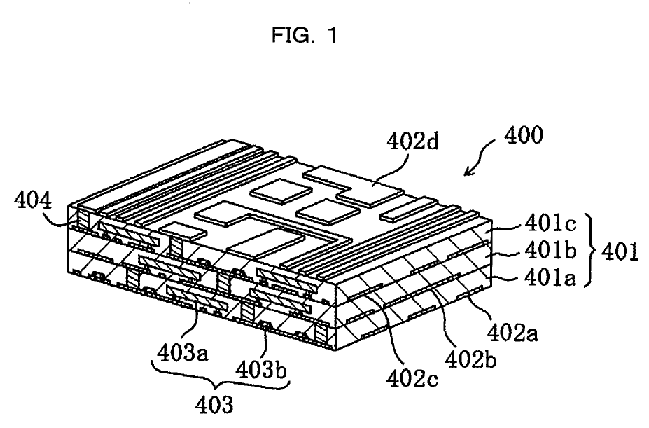

An overall structure of the circuit board 100 is such a structure that is illustrated in FIG. 1, wherein electronic components are mounted inside the board or on a surface of the board, or inside and on the surface of the board. In a part of the drawings used for the description of the present preferred embodiment including FIGS. 2A and 2B, the electronic components are not shown.

As illustrated in FIG. 2A, the board circuit 100 according to the present preferred embodiment comprises an upper-layer board 22, a lower-layer board 21, and a connecting resin layer 24 which connects the upper-layer board 22 and the lower-layer board 21. An insulator constitutes the connecting resin layer 24, and the upper-layer board 22 and the lower-layer board 21 constitute an insulating layer 20. A first solder 12 constitutes the solder marker 10 according to the present preferred embodiment, which is provided inside the insulating layer 20. A solder including Sn—Sb, for example, as its main constituent and having a first melting point constitutes the first solder 12. The solder marker 10 is housed in a housing chamber 25 provided inside the circuit board 100. More specifically, the solder marker 10 is provided on an electrode pattern 23 exposed in the housing chamber 25.

A first electronic component (not shown) is provided on an upper surface 20a or a lower surface 20b of the circuit board 100. The first electronic component is mounted on the circuit board 100 via a second solder (not shown). The second solder has a second melting point lower than the first melting point. A Pb free solder, for example, constitutes the second solder. A second electronic component (not shown) may be provided inside the insulating layer 20 (more specifically, between the upper-side board 22 and the lower-sideboard 21). In that case, the circuit board 100 is a component-incorporated board in which the second electronic component is incorporated.

A composite sheet including resin and inorganic filler constitutes the connecting resin layer 24. The solder marker 10 is disposed between the upper-layer board 22 and the lower-layer board 21. The non-melted first solder constitutes the solder marker 10. The housing chamber 25 is formed in a part of the connecting resin layer (composite sheet) 24, and the solder marker 10 is provided inside the housing chamber 25. More specifically, the solder marker 10 is disposed on the electrode pattern 23 of the lower-layer board 21 exposed in the housing chamber 25.

The first solder 12 constitutes the solder marker 10 illustrated in the drawing, and the first solder 12 is disposed on the electrode pattern 23 via flux 14. The solder marker 10 is a marker used for checking if the solder is re-melted. When the solder marker 10 reaches a predetermined temperature (more specifically, first melting point, that is, the melting point of the first solder 12), the first solder 12 is melted and shows the state illustrated in FIG. 2B.

FIG. 2B illustrates the state of the solder marker 10 indicating that the circuit board 100 reaches at least a predetermined temperature (first melting point), and a third solder (having the same melting point as that of the solder marker 10), which is a connecting member of the second electronic component (not shown) mounted in the circuit board 100, is thereby re-melted.

As illustrated in FIG. 2B, the first solder 12 constituting the solder marker 10 is melted and extends on the electrode pattern 23. Then, the non-melted first solder 12 illustrated in FIG. 2A and the first solder 12a illustrated in FIG. 2B which has been melted and extended are compared to each other. More specifically, shapes and characteristics of the solder marker 10 (non-melted first solder 12 and melted first solder 12a) are checked. Accordingly, it can be checked whether or not the third solder, which is a connecting member of the second electronic component, has been re-melted. The third solder is re-melted because the circuit board 100 is exposed to a temperature which is at least the first melting point (that is the first melting point).

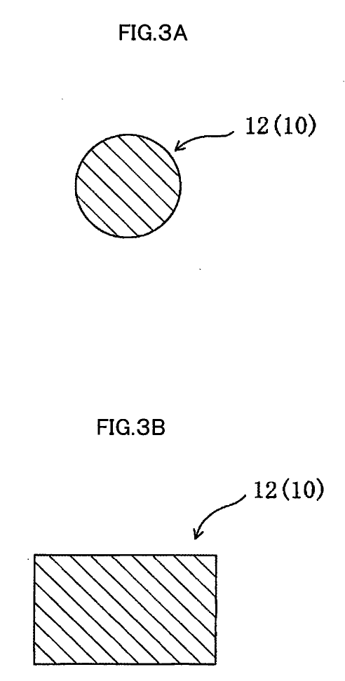

When the solder marker 10 made of a non-melted state of the first solder 12 as illustrated in FIG. 2A is X-ray illuminated and viewed from the above of the circuit board 100, the image illustrated in FIG. 3A is obtained. When the solder marker 10 made of a melted state of the first solder 12a as illustrated in FIG. 2B is X-ray illuminated and viewed from the above of the circuit board 100, the image illustrated in FIG. 3B is obtained. When a difference between the two shapes is distinguished, the solder marker test can be performed. The solder marker may be checked (judged whether or not melted) visually by an observer or automatically by an image recognition device. The electrode pattern 23 which receives the melted first solder 12 and thereby forms its substantial shape may be rectangular as illustrated in the drawing, or triangular, star-shaped, cross-shaped or of any other shapes. The solder marker test (judged whether or not melted) is not limited to a test in which X ray is used, and may be performed by an electrical test. More specifically, for example, the solder marker 10 made of the non-melted first solder 12 is disposed between two electrode patterns separated from each other and adjacent to each other so as to bridge the gap between them while keeping both the patterns insulated. Accordingly, it can be checked whether or not the solder marker 10 has been melted when the insulation between the two terminals is tested.

The solder marker 10 is preferably disposed in the vicinity of the second electronic component to be tested (and the third solder as a connecting member thereof). As a result, the temperature to which the second electronic component is exposed can be accurately tested in the vicinity thereof.

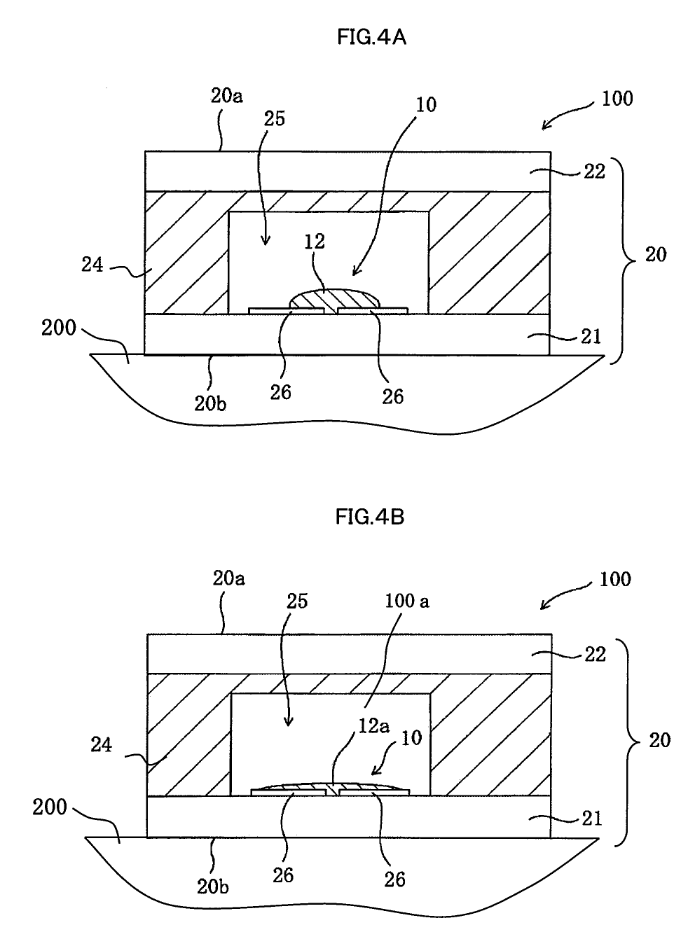

A testing method according to the present preferred embodiment is described in detail below. FIG. 4A illustrates the solder marker 10 constituted such that the non-melted first solder 12 is disposed on a pair of electrode patterns 26 and 26. In this state, the first solder 12 constituting the solder marker 10 is in a non-melting state. Therefore, the electrode patterns 26 and 26 and the first solder 12 are not metallically bonded to each other, and the gap between the pair of electrode patterns 26 and 26 is open (insulated). More specifically, electrical characteristics shown when the first solder 12 is not melted and disposed between the pair of electrode patterns 26 and 26 are different to electrical characteristics shown when the first solder 12 is melted and the pair of electrode patterns 26 and 26 is completely electrically conducted to each other (for example, resistance is higher).

When the solder marker 10 (first solder 12) reaches at least the predetermined temperature (first melting point) and is melted, the pair of electrode pattern 26 and 26 is short-circuited relative to each other due to the melted first solder 12a as illustrated in FIG. 4B. Therefore, when the short circuit due to the solder marker 10 is detected, it can be judged that the circuit board 100 was exposed to at least the predetermined temperature (first melting point) or the first solder 12 has been melted.

A cream solder may be used as the first solder 12 constituting the solder marker 10. In the state illustrated in FIG. 4A, the first solder 12, which is the cream solder, and the electrode patterns 26 and 26 are not metallically bonded to each other, and the gap between the pair of electrode patterns 26 and 26 are open. When the first solder 12, which is the cream solder, reaches at least the predetermined temperature (first melting point) and is melted, the melted first solder 12a makes the pair of electrode patterns 26 and 26 short-circuited relative to each other in a similar manner as illustrated in FIG. 4B. This transition is detected when the short circuit by the solder marker 10 made of the cream solder is detected. As a result, it can be judged that the circuit board 100 was exposed to at least the predetermined temperature (first melting point), or the first solder 12 was melted.

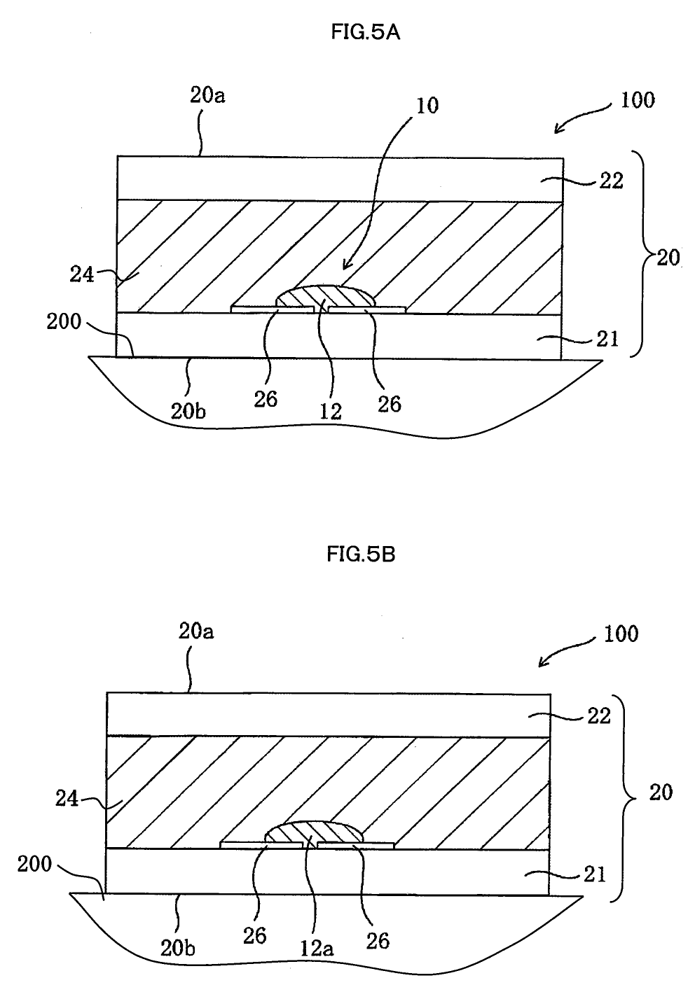

The solder marker 10 may be embedded in the connecting resin layer 24 as illustrated in FIGS. 5A and 5B. The solder marker 10 illustrated in FIG. 5A is constituted in a manner similar to the illustration in FIG. 4A, and the solder marker 10 is formed such that it is embedded in the connecting resin layer (composite sheet) 24. On the other hand, the solder marker 10 illustrated in FIG. 4A is housed in the housing chamber 25 provided in the connecting resin layer (composite sheet) 24.

In the constitution illustrated in FIG. 5A, the gap between the pair of electrode patterns 26 and 26 is open in the case where the non-melted first solder 12 is disposed on the pair of electrode patterns 26 and 26. When the first solder 12 reaches at least the predetermined temperature (first melting point) and is melted, the melted first solder 12a makes the pair of electrode patterns 26 and 26 short-circuited relative to each other as illustrated in FIG. 5B. Therefore, when the short circuit is electrically detected, it can be judged that the first solder 12 has been melted. Thus, the cream solder can be used as the first solder 12 for the solder marker 10 in the constitution wherein the solder marker 10 is embedded in the connecting resin layer 24.

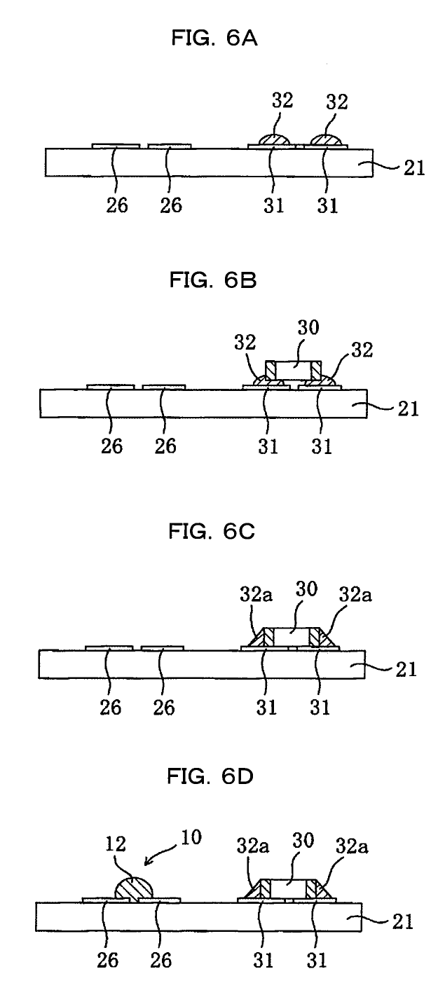

Referring to FIGS. 6A through 8B are described a method for manufacturing the component-incorporated board according to the present preferred embodiment, and an example of a re-melting testing method in which the solder marker 10 is used.

As illustrated in FIG. 6A, the lower-layer board 21 is prepared, and then, a third solder 32 is formed on a part (land 31) of the electrode pattern of the lower-layer board 21. The third solder 32 is a cream solder and is formed on the lands 31 by means of a printing process. The electrode patterns 26 for the solder marker 10 are formed on the lower-layer board 21. The electrode patterns 26 for the solder marker 10 can be constituted as illustrated in FIG. 4a or as illustrated in FIG. 2A.

As illustrated in FIG. 6B, a second electronic component 30 is disposed on the lands 31 of the lower-layer board 21 via the third solder 32. The second electronic component 30 may be a chip component (for example, chip capacitor, chip inductor or chip resistance) or a semiconductor element (for example, bear chip, chip size package (CSP) and the like). In FIG. 6B, a chip component is used as the second electronic component 30. After the second electronic component 30 is mounted on the wiring board 21 in FIG. 6B, a first reflow process is performed so that the third solder 32 is melted as illustrated in FIG. 6C. Then, the second electronic component 30 is bonded to the lands 31 with a melted third solder 32a.

Next, as illustrated in FIG. 6D, the first solder 12 is disposed on the electrode patterns 26 so that the solder marker 10 is formed. The first solder 12 constituting the solder marker 10 is formed from the same material as that of the third solder 32 for the second electronic component 30 or has a melting point equal to that of the third solder 32 (first melting point). In the present preferred embodiment, a solder including Sn—Sb as its main constituent (Sn—Sb based solder) is used as the first solder 12 and the third solder 32.

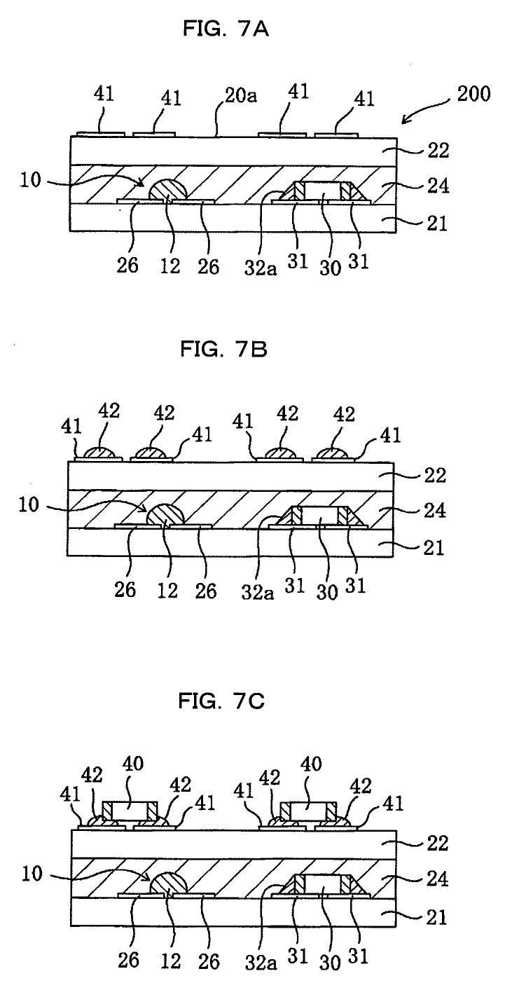

After that, as illustrated in FIG. 7A, the upper-layer board 22 is provided via the connecting resin layer 24 on the lower-layer board 21 on which the second electronic component 30 is mounted so that the second electronic component 30 is incorporated between the wiring boards 21 and 22. As a result of the multi-layer structure thus provided, a circuit board 200 in which the second electronic component 30 is incorporated can be formed. The solder marker 10 is provided between the upper-side board 21 and the lower-side board 22 in a manner similar to the second electronic component 30. The housing chamber 25 may be formed between the upper-side board 21 and the lower-side board 22 so that the solder marker 10 is housed in the housing chamber 25 as illustrated in FIG. 4A.

In the present preferred embodiment, an inter-layer connecting member (via) which electrically connects the lower-layer board 21 and the upper-layer board 22 can be formed in the connecting resin layer 24. The connecting resin layer 24 can be formed from a composite material including resin (for example, thermosetting resin and/or thermoplastic resin) and inorganic filler. In the present preferred embodiment, thermosetting resin is used as the resin. Further, the connecting resin layer 24 can be formed solely from the thermosetting resin without inorganic filler. An example of the thermosetting resin is epoxy resin or the like, and examples of the inorganic filler, if added, are Al₂O₃, SiO₂, MgO, BN, AlN and the like. When the inorganic filler is added, various physical properties can be controlled. Therefore, the composite material including the inorganic filler is preferably used for the formation of the connecting resin layer 24.

Wiring patterns 41 are previously formed on the upper surface 20a of the upper-layer board 11, and a second solder 42 is formed on lands 41 of the wiring patterns as illustrated in FIG. 7B. In the present preferred embodiment, a cream solder, which is used as the second solder 42, is formed on the upper-layer board 22 by means of a printing process. The second solder 42 is a solder having a melting point (second melting point) lower than the melting point of the first solder 12 (first melting point, and melting point of the third solder 32) constituting the solder marker 10.

The second melting point of the second solder 42 is lower than the melting point of the third solder 32 (≈first melting point) embedded in the circuit board 200 provided with the electronic component therein, because the melted third solder 32a contributing to the connection of the second electronic component 30 which is primarily incorporated in the circuit board 200 is re-melted when the second melting point of the second solder 42 is higher than the melting point of the third solder 32. When the melted third solder 32a is re-melted, air bubbles are generated in the third solder 32, which easily leads to troubles. Further, in the case where there are voids in the connecting resin layer 24 and the like provided in the vicinity of the melted third solder 32a, a driving force is generated by pressure increase resulting from thermal expansion and capillarity, and the driving force makes the re-melted third solder 32 penetrate into the voids, as a result of which the third solder 32 may outflow from an original position where it is disposed (on the pattern). In order to prevent the third solder 32 from re-melting, the melting points of the third solder 32 for the primary mounting and the second solder 42 for the secondary mounting are set so that they are different to each other.

Conductive particles having a melting point lower than that of the third solder 32 for the primary mounting or the first solder 12 for the solder marker can constitute the second solder 42. For example, a Pb free solder (for example, Sn—Ag—Cu based solder or Sn—Zn based solder), or a Pb solder (Sn-37Pb solder), which have a melting point (second melting point) lower than the melting point of the third solder 32 for the primary mounting (≈first melting point), constitutes the second solder 42.

Next, as illustrated in FIG. 7C, the first electronic component 40 is disposed on the lands 41 of the upper-layer board 22 via the second solder 42. The first electronic component 40 is a chip component and/or a semiconductor element in a manner similar to the second electronic component 30.

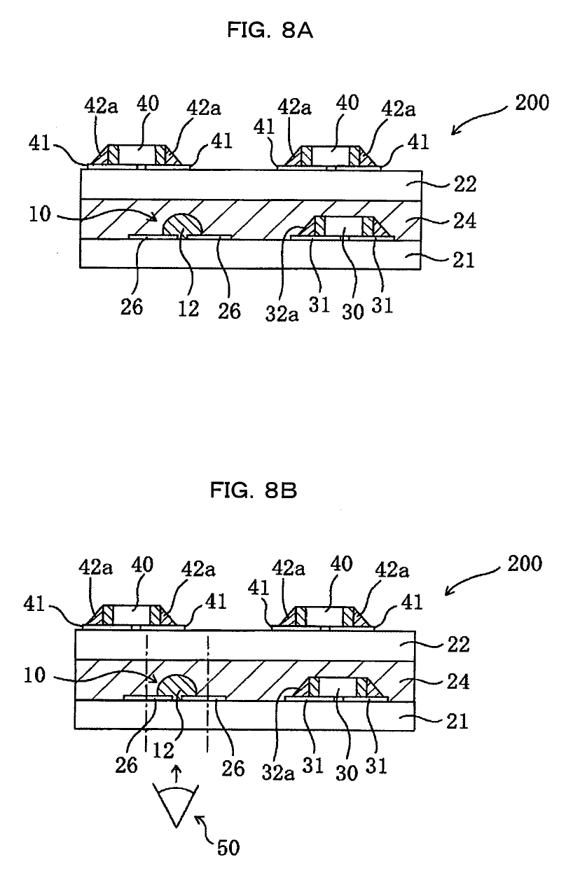

Next, as illustrated in FIG. 8A, a second reflow process is performed so that the second solder 42 is melted, and the first electronic component 40 is bonded to the lands 31 via the melted second solder 42a. Thus, the first electronic component 40 is mounted on the upper surface of the circuit board 200 in which the second electronic component 30 is incorporated. The second reflow process is performed at a temperature lower than that of the first reflow process, more specifically, at such a temperature that does not re-melt the third solder 32 (below the melting point of the third solder (≈first melting point).

Even if the temperature of the second reflow process is limitedly set to such a temperature that does not re-melt the third solder 32, a temperature of the circuit board (component-incorporated board) may exceed the set temperature due to variations in temperature in a reflow furnace or any other reasons. A reflow device, which measures and controls the temperature in the furnace, does not directly measure the temperature of the board (component-incorporated board or circuit board). Therefore, the third solder 32 may actually be re-melted when the actual temperature in the board is so high as to re-melt the third solder 32 even though the temperature in the reflow is set to such a temperature that does not re-melt the third solder 32.

After that, as illustrated in FIG. 8B, the solder marker 10 of the circuit board 200 is tested. More specifically, it is checked via the solder marker 10 whether or not the melted third solder 32a, which is the connecting member of the second electronic component 30 incorporated in the circuit board 200, has been re-melted.

In the case of the solder marker 10 constituted as illustrated in the drawing, the state of the solder marker 10 (open or short-circuited) can be judged through an electrical test. In the case where the solder marker 10 illustrated in FIGS. 2A and 2B is used, the re-melting can be checked through an X-ray measurement (50).

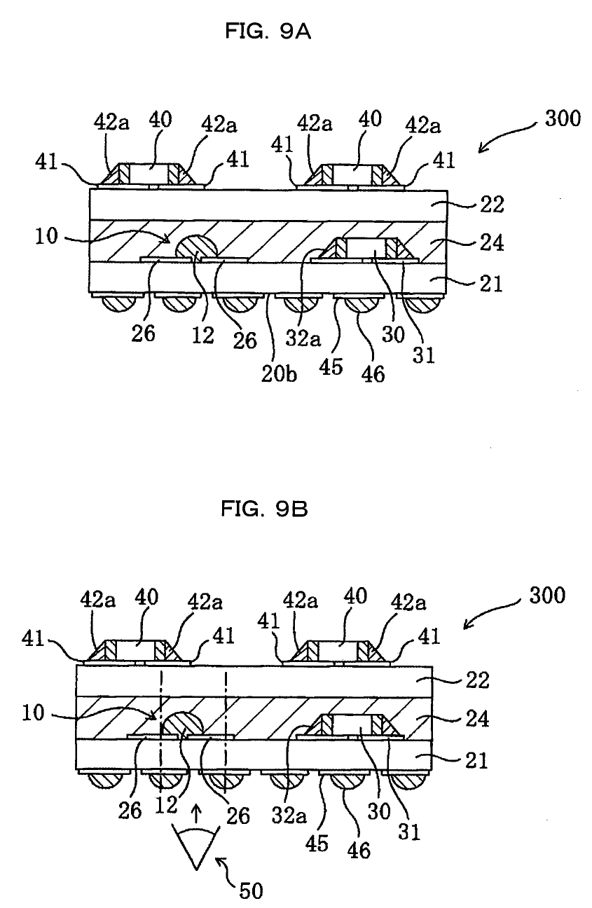

Further, the state of the solder marker 10 can be judged as illustrated in FIG. 9B after solder balls 46 are formed on the lower surface 20b of the circuit board 200 so that a component-incorporated module (or component-incorporated package) 300 is manufactured as illustrated in FIG. 9A. In order to manufacture the component-incorporated module 300, a both-surface wiring board is used as the lower-layer board 21, and the solder balls (or solder bumps) 46 are formed on terminals (lands) 45 of the lower-layer board 21. In the formation of the solder balls 46, solder balls for the ball grid array (BGA) can be used.

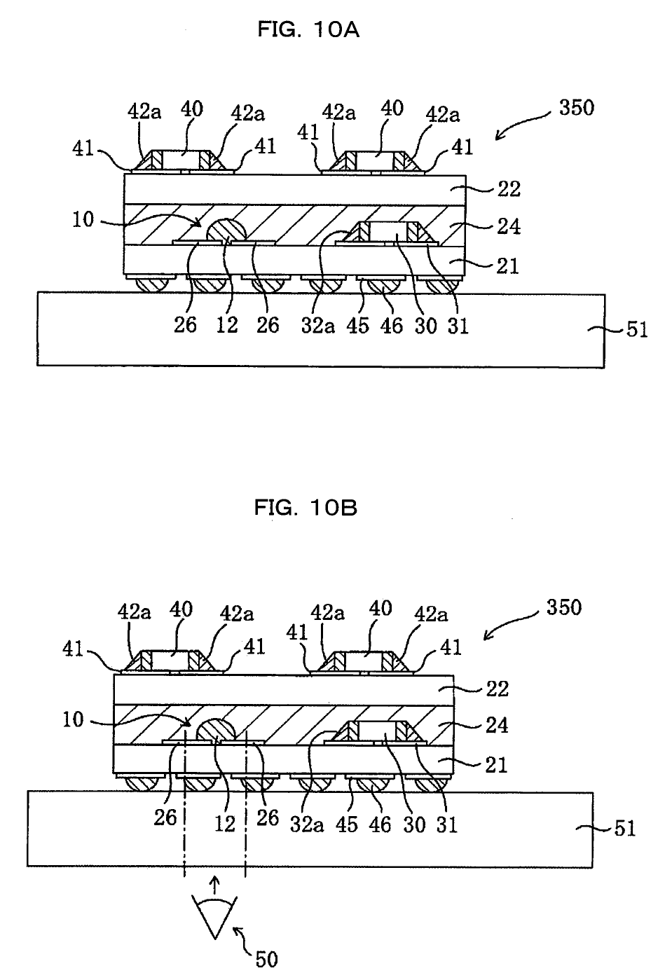

Further, as illustrated in FIG. 10A, a mounting body (component-incorporated module mounting body) 350 can be formed such that the component-incorporated module 300 illustrated in FIG. 9A or 9B is mounted on the wiring board 51 which serves as a mother board. In that case, as illustrated in FIG. 10B, the re-melting of the solder in the mounting body 350 can be checked by means of the solder marker 10.

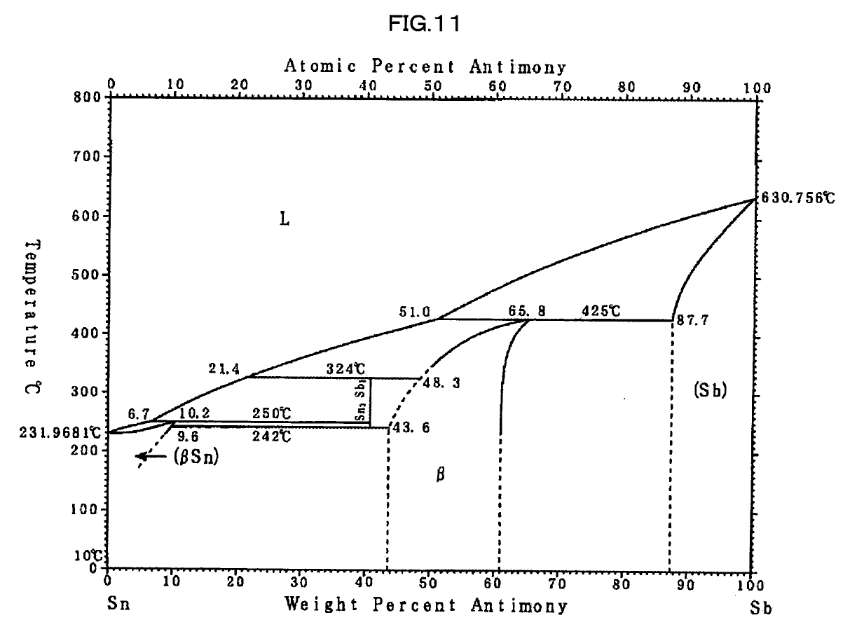

As the first solder 12 constituting the solder marker 10 can be used the solder material including Sn—Sb as its main constituent as described earlier. The solder material of this type is used because the melting point can be changed depending on the Sb content. FIG. 11 illustrates states of the Sn—Sb based material together with some melting points. For example, the melting point is 232° C. when Sb is 0%, and the melting point is 246° C. when Sb is 10%.

The Sn—Sb based solder is disadvantageously vulnerable to stress such as a thermal shock and easily undergoes cracks because an alloy composition is generally harder than a Pb—Sn eutectic crystal solder. However, in the constitution wherein the first solder 12 is embedded in the connecting resin layer 24 as described earlier, the before-mentioned disadvantage can be avoided, which is another merit of the constitution. The first solder 12 constituting the solder marker 10 is not necessarily limited to the Sn—Sb based solder.

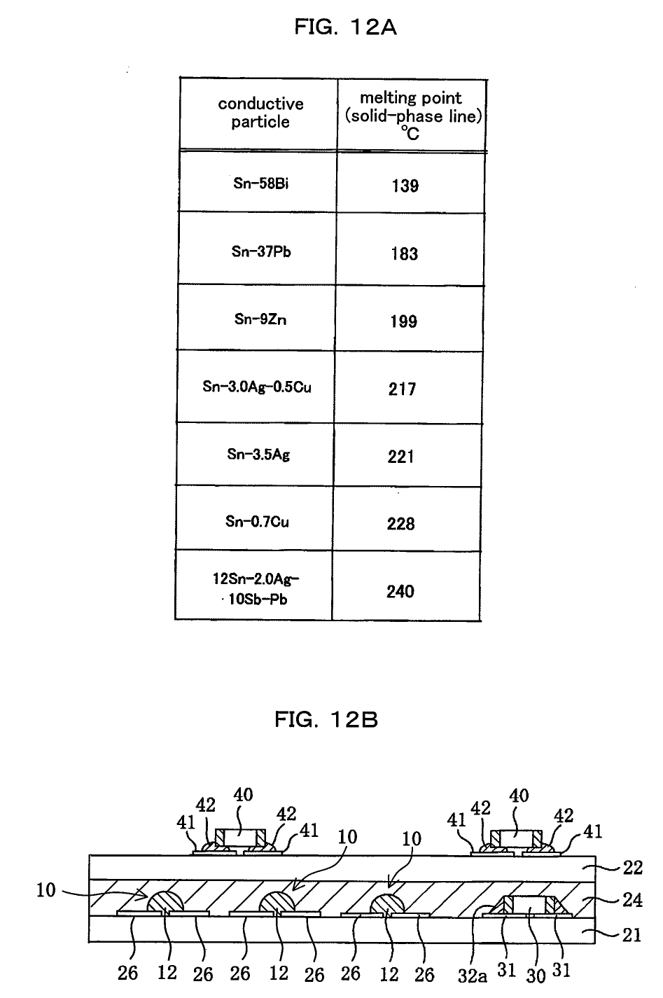

FIG. 12 is a table showing a relationship between the conductive particles used as the solder and the melting points (solid-phase lines). The first solder 12 constituting the solder marker 10 and the second and third solders 32 and 42 used for the first and second electronic components, respectively, can be selected from among these conductive particles in view of the different melting points. The conductive particles are not necessarily limited to those shown in this table.

According to the present preferred embodiment, the solder marker 10 mode of the solder 12 having the first melting point is provided, and the first electronic component 40 is mounted on the upper surface 20a of the circuit board 200 via the second solder 42 having the second melting point lower than the first melting point. Therefore, when the solder marker 10 provided in the circuit board 200 is tested, it can be checked whether or not the third solder 32 (connecting member of the second electronic component) having the melting point equal to the first melting point is re-melted. Therefore, it can be judged whether or not the third solder 32 of the second electronic component 30 incorporated in the circuit board 200 is re-melted, and the reliability of the circuit board 200 can be checked with a high accuracy.

Further, according to the present preferred embodiment, wherein the solder marker 10 is provided in the circuit board 200 provided with the electronic component therein (or circuit board 100 provided with no built-in electronic component therein), the solder marker 10 can be used to check whether or not the board is exposed to any temperature higher than the predetermined temperature due to the variability (bias and variability of the reflow temperature) in the reflow process. Therefore, the reliability of the product can be prevented from deteriorating.

The solder marker 10 according to the present preferred embodiment can be used not only for checking if the re-melting occurred in the circuit board 200 in which the electronic component is incorporated but also for other purposes. For example, it can be effectively checked whether or not the reflow temperature is beyond the appropriate temperature in the constitutions illustrated in FIGS. 2 through 5B. This effect can be similarly obtained in the circuit board provided with no built-in electronic component therein. Below is given a description in relation to the effect.

A factor for deteriorating the quality of the board is a significant increase of the reflow temperature. Particularly after the Pb free is made available in an extensive range, the reflow temperature in the reflow process is increasing, which has created severe circumstances for the board in the electronic component mounting process. When the reflow temperature is too high, the resin constituting the board is deteriorated. As a result, the adhesion power of the lands may be weakened and the separation between the land and the electrode tends to occur in the inner and outer layers. In the case where a problem can be easily detected from an external appearance, appropriate measures can be taken. However, in the case where damage occurs inside the board and cannot be observed from outside, such problems as the separation of the lands or migration (because moisture easily remains in a separated section) due to the separation of the lands in the inner-layer electrode may arise after a final product is fabricated. The reflow device is configured to control the temperature inside the device; however, it cannot control the temperature of the product itself such as the board or the like. Therefore, in some cases, the board may be exposed to high temperatures due to the variability. Therefore, it is a significantly useful technology to provide the marker 10 in the board so as to check whether or not the reflow temperature is at least the appropriate temperature.

A group of first solders 12 of different types (respectively having different melting points) may constitute the solder marker 10 according to the present preferred embodiment so that they function as temperature markers. For example, as illustrated in FIG. 12B, a plurality of different solder markers 10 are produced from a group of first solders 12 selected from the conductive particles illustrated in FIG. 12A, and then, it can be checked by the solder markers 10 how high the board temperature (for example, in-substrate temperature) has reached in the reflow process.

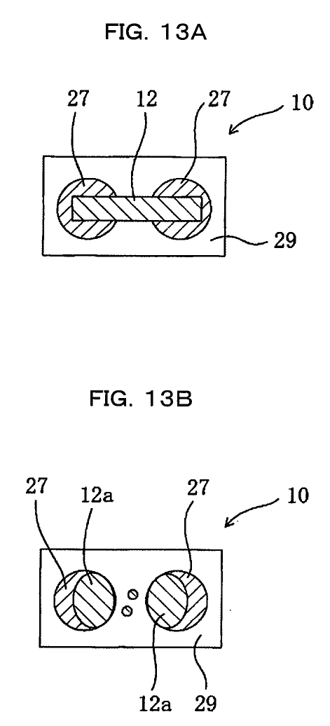

The solder marker 10 according to the present preferred embodiment may be modified as follows. In FIGS. 13A and 13B, the solder marker 10 is viewed from above. The solder marker 10 illustrated in FIG. 13A is constituted such that a marker member made of the non-melted first solder 12 acts as a bridge between electrode patterns 27 around which a resist (solder resist) 29 is formed. When the first solder 12 is melted, a surface tension is generated. Therefore, as illustrated in FIG. 13B, the solder marker 10 shows a state different to the state before the melting illustrated in FIG. 13A as the first solder 12 is melted. The test by the solder markers can be performed when the forgoing change is observed.

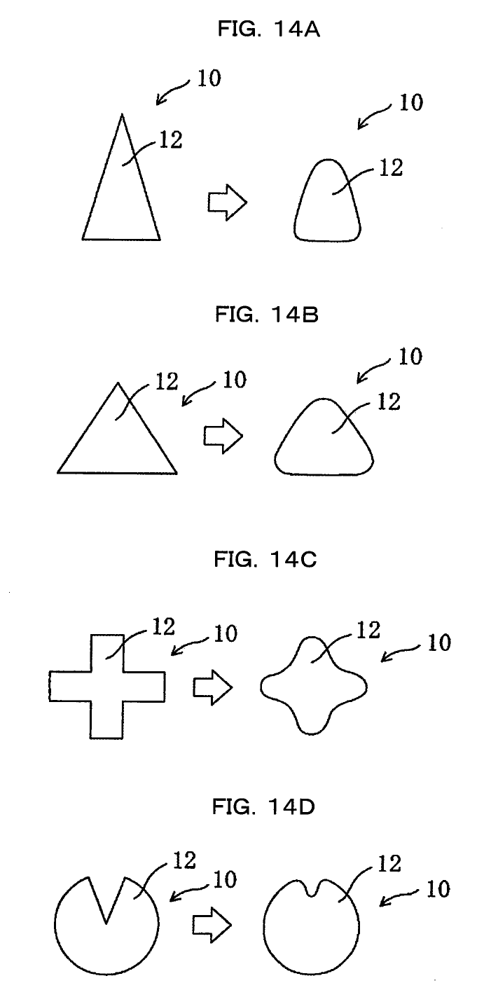

In the case where the solder 12 is formed into a shape having corners in its outer periphery in a plan figure, the corners are deformed and rounded by a surface tension generated when the solder 12 is melted. Utilizing this theory, the solder markers 10 illustrated in FIGS. 14A-14D can be provided. Shapes on the left side in FIGS. 14A-14D illustrate shapes of the solder markers 10 in which the non-melted first solder 12 is used. These solder markers 10 may be deformed and rounded in the corner sections thereof when melted and thereby take shapes illustrated on the right side in FIGS. 14A-14D. Therefore, when these changes of the shapes are observed, the test in which the solder marker 10 is used can be performed.

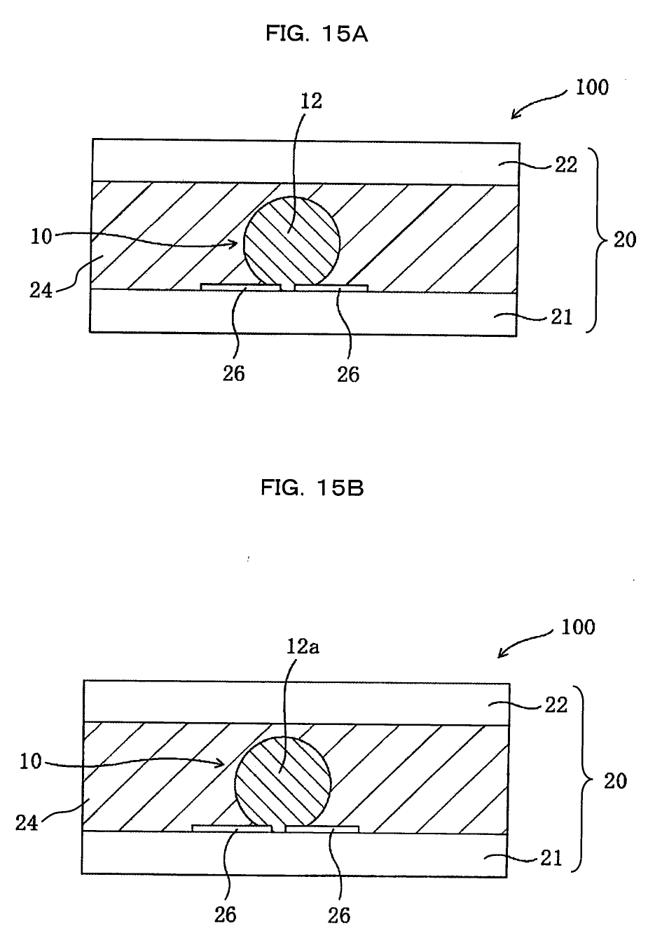

In the constitutions illustrated in FIGS. 4 and 5, the first solder 12 in the form of cream solder is used for the formation of the solder marker 10. However, the solder marker 10 may be formed from a solder ball made of the first solder 12 as illustrated in FIG. 15.

In the state illustrated in FIG. 15A, the first solder 12 formed in the shape of the solder ball is not melted, and therefore, the first solder 12 in the shape of the solder ball and the electrode 26 are not metallically bonded to each other. Therefore, a gap between the electrodes 26 is open. When the first solder 12 in the shape of the solder ball is melted, the melted first solder 12a in the shape of the solder ball and the electrodes 26 are metallically bonded to each other, and the electrodes 26 are short-circuited relative to each other as illustrated in FIG. 15B. When the difference between the states is detected, the solder market test can be performed.

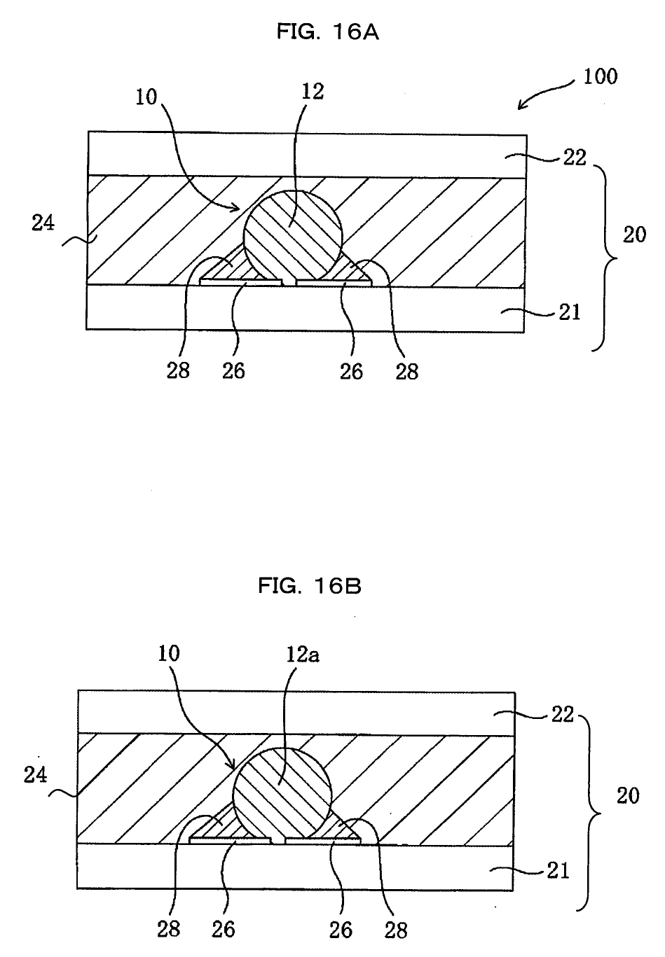

As illustrated in FIG. 16A, an adhesive 28 which bonds the first solder 12 and the electrodes 26 illustrated in FIG. 15A may be provided in order to fix the first solder 12 to prevent it from being shifted by the flow of the resin when the first solder 12 is embedded in the connecting resin layer (composite sheet) 24. Even in the constitution wherein the first solder 12 is fixed by the adhesive 28, when the first solder 12 is melted, the melted first solder 12a and the electrodes 26 are metallically bonded as illustrated in FIG. 16B, and the electrodes 26 are thereby short-circuited relative to each other. Therefore, the solder marker test can be performed.

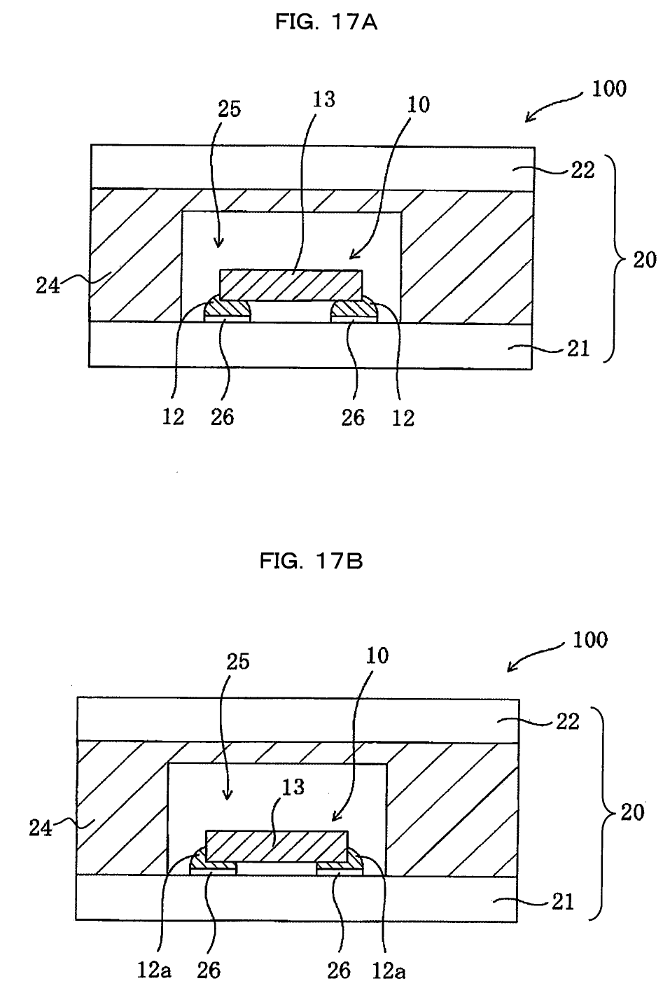

As illustrated in FIG. 17A, the combination of the first solder 12 and a conductive member (typically, metallic member or 0Ω chip resistance) 13 may constitute the solder marker 10. In this case, when the metallic member 13 is disposed on the non-melted first solder 12 (for example, cream solder), a gap between the electrodes 26 is electrically open since the first solder 12 is not melted. On the other hand, when the first solder 12 is melted, the melted first solder 12a and the electrodes 26 are metallically bonded to each other as illustrated in 17B and the melted first solder 12a and the metallic member 13 are metallically bonded to each other. Therefore, component characteristics shown in the case where the electrodes 26 are short-circuited are exhibited. According to the difference between the states, the solder marker test can be performed.

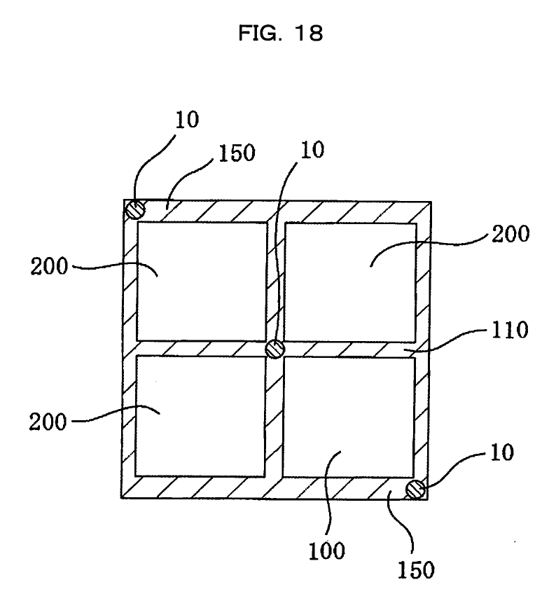

In the present preferred embodiment, the solder marker 10 is provided inside the board; however, it is not necessarily provided inside the board. For example, in the case where the circuit board 200 provided with the electronic component therein is manufactured by means of a sheet (for example, composite sheet for obtaining a large number of modules) for obtaining a large number of modules (circuit board 200 provided with the electronic component therein and the like) 110 as illustrated in FIG. 18, the solder marker 10 may be provided in a section (outer frame 150) other than a region where the circuit board 200 provided with the electronic component therein is provided. In the case where the solder marker 10 is provided at such a section, the solder marker test can be performed without wasting an area of the board, thereby bringing efficiency to area utilization.

The circuit board 200 in which the electronic component is incorporated (component-incorporated module 300, mounting body 350) thus described is installed in an electronic device for suitable use, and is particularly suitably used in a mobile electronic device (for example, mobile telephone, PDA or the like) in which strict restrictions are imposed on a mounting area. The circuit board 200 can also be used in an electronic device such as a home electronic appliance (digital camera or the like).

The preferred embodiment of the present invention was thus far described; however, the description made so far does not impose any restrictions on the present invention, and various modifications of the preferred embodiment are also available.

### INDUSTRIAL APPLICABILITY

The present invention can provide a component-incorporated board or a circuit board comprising a solder marker capable of checking if solder is re-melted.

1. A circuit board comprising:
an insulating layer;
a first electronic component mounted on the insulating layer; and
a solder marker provided on the insulating layer, wherein
a first solder having a first melting point constitutes the solder maker, and the solder maker is provided inside the insulating layer, and
the first electronic component is mounted on the insulating layer via a second solder having a second melting point lower than the first melting point.

2. The circuit board as claimed in claim 1, wherein
the circuit board is a primary board mounted on a secondary board.

3. The circuit board as claimed in claim 1, further comprising an electrode pattern provided on the insulating layer, wherein
the solder marker is provided on the electrode pattern.

4. (canceled)

5. The circuit board as claimed in claim 1, wherein
a housing chamber is provided inside the insulating layer, and
the solder marker is housed in the housing chamber.
the solder marker is provided on the electrode pattern.

7. The circuit board as claimed in claim 1, wherein
the solder marker is embedded in the insulating layer.

8. The circuit board as claimed in claim 1, wherein
the first electronic component is mounted on a surface of the insulating layer.

9. The circuit board as claimed in claim 1, wherein
the first solder is a non-melted solder.

10. The circuit board as claimed in claim 9, wherein
the non-melted solder is in the form of a cream solder.

11. The circuit board as claimed in claim 9, further comprising an adhesive for fixing the solder maker to the insulating layer.

12. The circuit board as claimed in claim 1, wherein
the first solder includes Sn—Sb as its main constituent.

13. The circuit board as claimed in claim 1, further comprising a second electronic component mounted on the insulating layer via a third solder having a melting point equal to the first melting point, and
the first electronic component is mounted on a surface of the insulating layer.

14. The circuit board as claimed in claim 13, wherein
the second electronic component is provided inside the insulating layer.

15. The circuit board as claimed in claim 13, wherein
the solder marker is a marker for checking characteristics of the circuit board exhibited when another electric member is connected to the circuit board.

16. The circuit board as claimed in claim 15, wherein
the characteristics of the circuit board are connection characteristics between the circuit board deteriorating as the third solder is re-melted and the second electronic component.

17. The circuit board as claimed in claim 1, wherein
the solder marker has corners in an outer periphery thereof when the board is viewed in a plan figure.

18. The circuit board as claimed in claim 1, wherein
a plurality of the solder markers are provided, and the first solders respectively having the different first melting points constitute the plurality of solder markers.

19. The circuit board as claimed in claim 1, wherein
the insulating layer comprises an upper-layer board, a lower-layer board facing the upper-side board, and a connecting resin layer for bonding the upper-layer board and the lower-layer board, and
the solder marker is provided between the upper-layer board and the lower-layer board.

20. The circuit board as claimed in claim 19, wherein
the connecting resin layer includes thermosetting resin and inorganic filler.

21. The circuit board as claimed in claim 1, wherein
the second solder is a Pb free solder.

22. A method for checking characteristics of a circuit board on which an electronic component is mounted via solder exhibited when another electronic member is connected thereto, wherein
a solder maker having a first melting point is previously provided in the circuit board, and such another electronic member is connected to the circuit board, and
it is judged whether or not the solder maker is re-melted after such another electronic component is connected so that it is judged whether or not the circuit board is exposed to the first melting point after such another electronic member is connected.

23. The method for checking characteristics of a circuit board as claimed in claim 22, wherein
t is judged whether or not the solder marker is melted after such another electric component is connected so that connection characteristics between the circuit board and the electronic component are judged.

24. The method for checking characteristics of a circuit board as claimed in claim 23, wherein
the electronic component is mounted on the circuit board via a solder having a melting point equal to the first melting point, and
it is judged whether or not the solder marker is melted after such another electric component is connected so that it is judged whether or not the solder is exposed to the first melting point.

25. The method for checking characteristics of a circuit board as claimed in claim 22, wherein
the electronic component is provided inside the insulating layer.

26. The method for checking characteristics of a circuit board as claimed in claim 25, wherein
the solder marker is provided inside the insulating layer.

27. The method for checking characteristics of a circuit board as claimed in claim 22, wherein
the judgment is made by illuminating a transmitted beam on the circuit board and observing a transmitted light thereby obtained.

28. The method for checking characteristics of a circuit board as claimed in claim 27, wherein
the judgment is made by illuminating the transmitted beam on the circuit board and image-recognizing the transmitted light thereby obtained.

29. The method for checking characteristics of a circuit board as claimed in claim 22, wherein
the judgment is made by transmitting an electrical signal to the circuit board and checking signal characteristics of the signal.

30. A method for manufacturing a circuit board on which an electronic component is mounted, including:
a step of providing a solder marker comprising a first solder having a first melting point in the circuit board and mounting the electronic component on the circuit board via a solder having a melting point equal to the first melting point; and
a step of mounting another electronic component in the circuit board via a second solder having a second melting point lower than the first melting point.

31. The method for manufacturing a circuit board as claimed in claim 30, wherein
a plurality of the circuit boards are formed as a single unit into a large-size board, and
the solder marker is provided outside a region occupied by the respective circuit boards in the large-size board.
